(19) United States
(12) Patent Application Publication
(10) Pub. No.: US 2026/0010677 A1
(43) Pub. Date: Jan. 8, 2026

(54) OPTIMAL LOAD CURTAILMENT CALCULATING METHOD BASED ON LAGRANGE MULTIPLIER AND APPLICATION THEREOF

(71) Applicant: TIANJIN UNIVERSITY, Tianjin (CN)

(72) Inventors: Kai HOU, Tianjin (CN); Zeyu LIU, Tianjin (CN); Hongjie JIA, Tianjin (CN); Dan WANG, Tianjin (CN); Yunfei MU, Tianjin (CN); Xiaodan YU, Tianjin (CN); Lewel ZHU, Tianjin (CN)

(21) Appl. No.: 19/329,048

(22) Filed: Sep. 15, 2025

Related U.S. Application Data
(63) Continuation of application No. 17/438,363, filed on Sep. 10, 2021.

(30) Foreign Application Priority Data
Aug. 29, 2019 (CN) 201910805095.7

(51) Int. Cl. G06F 30/20; G06F 17/16

(52) U.S. Cl. CPC G06F 30/20; G06F 17/16

(57) ABSTRACT

There is provided an optimal load curtailment calculating method based on Lagrange multiplier and an application thereof in power system reliability assessment, wherein the calculating method includes the following steps: inputting all system states to be analyzed for reliability assessment and establishing corresponding optimal load curtailment models; classifying the optimal load curtailment models according to Lagrange multiplier to obtain several sets; and solving the optimal load curtailment models in each set by using Lagrange multipliers to obtain an optimal load curtailment corresponding to the system state. A processor executing the method is integrated as a part of a controller with a power system reliability assessment service, and then the power system uses the controller to control the power system by using data from the power system reliability assessment device maintain grid stability and reduce power consumption.

### CROSS-REFERENCE TO RELATED APPLICATION

This Application is a continuation-in-part application of the US Application with the application Ser. No. 17/438,363, which is a national stage application of PCT/CN2019/103669. This application claims priorities from US Application with the application Ser. No. 17/438,363, filed Sep. 10, 2021, and PCT Application No. PCT/CN2019/103669, filed Aug. 30, 2019, and from the Chinese patent application 201910805095.7, filed Aug. 29, 2019, the contents of which are incorporated herein in the entirety by reference.

### TECHNICAL FIELD

The present invention relates to the field of power system reliability assessment, and more particularly to an optimal load curtailment calculating method based on Lagrange multiplier and an application thereof in power system reliability assessment.

### BACKGROUND OF THE PRESENT INVENTION

Energy security is a priority area of national security for all countries and an overarching and strategic issue concerning the national economy and people's livelihood. Power system is a main energy supply system, the primary objective of which is to supply users with safe, reliable and low-cost electricity. Owing to environmental impact, component aging, etc., power system components may fail randomly, which can cause power outages and load curtailment. This is a risk source of the power system. Both the probability and the impact of system failure should be considered in power system reliability assessment, and quantitatively assessing the power system risks with reliability indices is of great guiding significance for the planning, design, operation, and maintenance of power systems.

In recent years, with the rapid development of renewable energy such as wind energy and photovoltaic energy, the randomness and intermittence of the generation system are greatly enhanced. As a result, it brings more uncertainties in the power system reliability assessment. Moreover, the differences of load curves in different industries and regions increase with the development of society and division of labor. Thus, it is necessary to use various load curves to describe the actual time-varying loads of the power system, which increases the difficulties of reliability assessment. In general, traditional reliability assessment methods tend to use a unified probability distribution of load and renewable energy output, however, a great error often appears when load types and distributed energy resources become more various and complex. Therefore, different probability distributions should be used for different loads and renewable generations, to provide more accurate power system reliability assessment results.

However, multiple types of loads and renewable generations can lead to a myriad of system states. With the expansion of power systems, the exponentially growing system states will impose a large computational burden for the reliability assessment. Most existing researches like sorting and filtering, variance reduction, clustering, etc., focus on reducing the number of system states to be analyzed. To this end, only the representative states are selected and analyzed in order to improve the efficiency of reliability assessment. Nevertheless, owing to the system scale and limitation of accuracy, it inevitably entails a huge number of selected system states to analyze, which seriously restricts the efficiency of power system reliability assessment and cannot satisfy the requirements of efficiency and accuracy for online applications. Therefore, an efficient and accurate reliability assessment method for power systems with multiple types of loads and renewable generations is a technical problem needed to be solved in this field

### SUMMARY OF THE PRESENT INVENTION

An objective of the present invention is to overcome the defects o the prior art, and to provide an optimal load curtailment calculating method based on Lagrange multiplier and an application thereof in power system reliability assessment. The method uses the Lagrange multiplier to calculate the optimal load curtailment and other impacts of system states to be assessed, which can speed up the system state analysis and thus improves the overall efficiency of power system reliability assessment.

The present invention solves the practical problems by adopting the following technical solutions.

An optimal load curtailment calculating method based on Lagrange multiplier includes the following steps:
Step 1: inputting all system states s to be analyzed for the reliability assessment, and establishing corresponding optimal load curtailment models, namely:

$$\begin{matrix}min & {c}^{T} x \\ s . t . & Ax = b , x \geq 0\end{matrix} \qquad ( 1 )$$

Where x is a variable vector; A is a coefficient matrix; b is a right-hand-side vector; and c is a cost coefficient vector;
Step 2: classifying the above optimal load curtailment models into a plurality of sets by the Lagrange multiplier λₛ; and
Step 3: solving all the optimal load curtailment models in each set by the Lagrange multiplier λₛ of the set, to obtain optimal load curtailments f_{LC_S} of the system states.

Wherein, the step 2 includes following steps:
comparing an unclassified optimal load curtailment model with a classified one, and the two models belong to the same set if the Lagrange multipliers of the two models are the same;
determining whether the Lagrange multipliers of the two optimal load curtailment models are the same includes following steps:
adopting the judgment criterion to determine whether the different vectors A, b and c of the two models will lead to different Lagrange multipliers λₛ;
the maximum time of judgment is proposed, if it is exceeded, an optimal load curtailment model with the same Lagrange multiplier λₛ is not found, and this optimal load curtailment model is regarded as a single set; and
comparing and judging the values A, b and c of the two models in descending order according to the similarity thereof.

In Step 2, the Lagrange multipliers λₛ of all the optimal load curtailment models in each set are the same.

In the “comparing an unclassified optimal load curtailment model with a classified one” of Step 2, the Lagrange multiplier of the classified optimal load curtailment model is calculated by an optimization calculation method.

The Step 3 includes the following steps:
calculating the optimal load curtailments f_{LC_s} of the system states s by the Lagrange multipliers λₛ:

$${f}_{LC \_ s} = {λ}_{s} b \qquad ( 2 )$$

Where b can be obtained from the optimal load curtailment model established in Step 1.

To solve the problems of the prior art, the following technical solution is also adopted in the present invention.

An application of the optimal load curtailment calculating method based on Lagrange multiplier in power system reliability assessment is provided. Specifically, the optimal load curtailment calculating method based on Lagrange multiplier is applied in power system reliability assessment to establish a power system reliability assessment device which includes an input and initialization module, a system state selection module, a state impact analysis module, and a reliability indices calculation module.
Module A. the input and initialization module is configured to input power system data, component reliability data and preset parameters of reliability assessment methods, including topological structure, branch parameters, component parameters, load data, renewable generation locations, renewable generation output data, and reliability parameters of components.
Module B. the system state selection module is configured to select the system states to be analyzed for the reliability assessment, including component contingency state, load time sequence state, and renewable generation output time sequence state. The system state selection method specifically includes State Enumeration (SE) technique, Monte Carlo Simulation (MCS) method, and improved methods of the SE technique and the MCS method.
Module C. the state impact analysis module is configured to analyze the impact of the system states selected by the Module B. The present invention computes the impact of the contingency state by the optimal load curtailment calculating method based on Lagrange multipliers and represents the impact by the load curtailments and all related indices.
Module D. the reliability indices calculation module is configured to compute the reliability indices of the power system based on the impact analysis results of the system states.

The advantages and beneficial effects of the present invention are as follows.

The core idea of the present invention, a Lagrange multiplier-based optimal load curtailment calculating method and application thereof in power system reliability assessment, is to establish Lagrange-multiplier-based linear functions between the optimal load curtailments and the system states. The iterative optimization processes of the traditional optimal load curtailment calculating method are substituted with the simple matrix multiplications. Thus, it can greatly reduce the amount of computation, improve the calculation speed without compromising the calculation accuracy. We can achieve an efficient and accurate reliability assessment for power systems with multiple types of loads and renewable generations. Moreover, the present invention has good compatibility. Since the idea of the present invention is to speed up the state analysis process of a single state, rather than to reduce the number of system states, the present invention can be integrated with a lot of existing research to obtain a more efficient and accurate reliability assessment method.

### BRIEF DESCRIPTION OF THE DRAWINGS

The present invention includes the drawings illustrated herein, which are used to provide a further understanding of the embodiments thereof. The drawings of the present invention are not meant to limit the embodiments of the present invention.

FIG. 1 is a flowchart of an optimal load curtailment calculating method based on Lagrange multiplier;

FIG. 2 is an application flowchart of the optimal load curtailment calculating method based on Lagrange multiplier in power system reliability assessment;

FIG. 3 is a topological structure diagram of the RTS79 system;

FIG. 4A is an annual load curve of the first load (LA);

FIG. 4B is an annual load curve of the second load (LB);

FIG. 4C is an annual load curve of the third load (LC);

FIG. 5A is an annual output curve of photovoltaic power;

FIG. 5B is an annual output curve of wind power;

FIG. 6 is a comparison of relative errors of EENS indices by four methods for the RTS-79 system reliability assessment in Scenario 1;

FIG. 7 is a comparison of relative errors of EENS indices by four methods for the RTS-79 system reliability assessment in Scenario 2;

FIG. 8 is a topological structure diagram of the IEEE118-bus system;

FIG. 9 is a comparison of relative errors of EENS indices by four methods for the IEEE118-bus system reliability assessment in Scenario 1;

FIG. 10 is a comparison of relative errors of EENS indices by four methods for the IEEE118-bus system reliability assessment in Scenario 2; and

FIG. 11 is a block diagram illustrating an exemplary computing system in which the present system and method can operate.

### DETAILED DESCRIPTION OF THE PRESENT INVENTION

In order to make the purposes, technical solutions and advantages of the present invention more clear, a further description of the optimal load curtailment calculating method based on Lagrange multiplier and an application thereof in power system reliability assessment is presented with reference to the embodiments thereof and accompanying drawings.

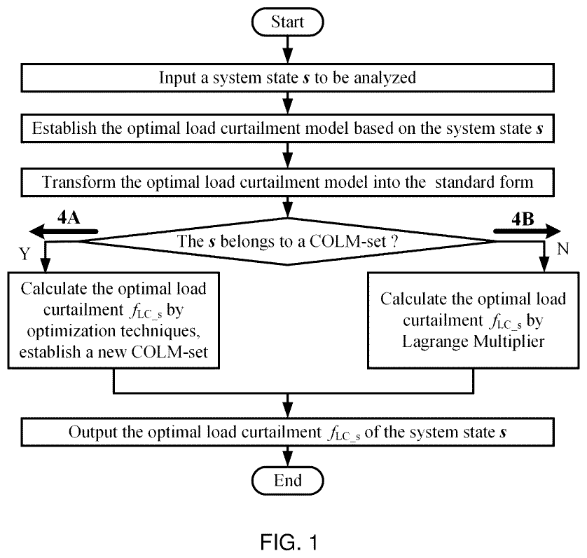

An optimal load curtailment calculating method based on Lagrange multiplier, as shown in FIG. 1, includes steps as follows.
Step 1: input the data related to system states s to be analyzed for the reliability assessment, specifically including the topological structure of power system, branch parameters, component parameters, load data of system states to be analyzed, renewable generations locations, renewable energy output levels, and failure components.
Step 2: optimal load curtailment models are established based on the system states s in the Step 1, and transformed into standard form by using the slack variables and surplus variables.

In each optimal load curtailment model, the minimum load curtailment is the objective function, active and reactive power output of generations, node voltage, and phase angle are used as variables, and node power balance, branch power flow limits, and upper and lower limits of variables are used as equality and inequality constraints. The model can be a DC model, a linearized AC model, and an AC model. These models are transformed into the standard model by introducing slack variables and surplus variables:

$$\begin{matrix}min & {c}^{T} x \\ s . t . & Ax = b , x \geq 0\end{matrix} \qquad ( 1 )$$

where x is the voltage, phase angle, power injection, slack variables, and surplus variables of the buses; A is a coefficient matrix, which represents the topological relation of the system and the slack relation of the variables; b is the branch power flow limits, the upper and lower limits of variables and the power balance value of the buses; and c is a cost coefficient vector such as penalty cost of load curtailments.
Step 3: the standard optimal load curtailment model in Step 2 is used to determine whether a system state s of the Step 1 belongs to a co-Lagrange-multiplier set (COLM-set). If so, the Lagrange multiplier λₛ of the system state s is obtained, go to Step 4B, otherwise, go to Step 4A.

If the system state from the Step 1 is the first system state to be analyzed, i.e., the optimal load curtailment calculating method based on Lagrange multiplier has not been performed before, Step 4A can be performed directly.

The Step 3 specifically includes the following steps: comparing the standard optimal load curtailment model in the Step 2 with the existing COLM-sets, and determining whether the system state s in the Step 1 belongs to a COLM-set. The model structure of the system state s is similar to that of the system state to be compared with, but there may be several differences in the values of the models. Thus, several judgment criteria are adopted depending on where the differences occur.
\textcircled{1} If the difference occurs in the cost coefficient vector c, it is assumed that the model in the Step 2 is c+Δc, and the model corresponding to the system state to be compared with is the vector c. If formula (2) is met, the two system states belong to the same COLM-set.

$${( c + Δ c )}^{T} - {( {c}_{B} + Δ {c}_{B} )}^{T} {B}^{- 1} A \leq 0 \qquad ( 2 )$$

As the cost coefficient vector c is different, the Lagrange multiplier As of the system state s in the Step 1 is:

$${λ}_{s} = {( {c}_{B} + Δ {c}_{B} )}^{T} {B}^{- 1} \qquad ( 3 )$$

\textcircled{2} If the difference occurs in the branch power flow limits b, it is assumed that the model in the Step 2 is b+Δb, and the model corresponding to the system state to be compared with is the branch power flow limits b. If formula (4) is met, the two system states belong to the same COLM-set.

$${B}^{- 1} ( b + Δ b ) \geq 0 \qquad ( 4 )$$

The Lagrange multiplier λₛ of the system state s in the Step 1 is:

$${λ}_{s} = {c}_{B}^{T} {B}^{- 1} \qquad ( 5 )$$

\textcircled{3} If the difference occurs in a column vector pₖ in the coefficient matrix A, it is assumed that the model in the Step 2 is pₖ+Δpₖ, and the model corresponding to the system state to be compared with is the column vector pₖ. If the column vector pk does not belong to the optimal basis B, (i.e., the corresponding variable xₖ is not the basic variable), and formula (6) is met, the two system states belong to the same COLM-set.

$${c}_{k} - {c}_{B}^{T} {B}^{- 1} ( {p}_{k} + Δ {p}_{k} ) \leq 0 \qquad ( 6 )$$

where Cₖ is the cost coefficient of the corresponding variable Xₖ. The Lagrange multiplier λₛ of the system state s in the Step 1 is:

$${λ}_{s} = {c}_{B}^{T} {B}^{- 1} \qquad ( 7 )$$

\textcircled{4} If the variable x changes, it is assumed that a new variable Xₙ₊₁ is added to the model of the system state to be compared in the Step 2. The cost coefficient Cₙ₊₁ and coefficient matrix column vector pₙ₊₁ are added accordingly. If formula (8) is met, the two system states belong to the same COLM-set.

$${c}_{n + 1} - {c}_{B}^{T} {B}^{- 1} {p}_{n + 1} \leq 0 \qquad ( 8 )$$

The Lagrange multiplier λₛ of the system state s in the Step 1) is:

$${λ}_{s} = {c}_{B}^{T} {B}^{- 1} \qquad ( 9 )$$

Based on the above judgment criteria, if the COLM-set to which the system state s in the Step 1 belongs, is found, go to Step 4B, otherwise, go to Step 4A.

Step 4A: the optimal load curtailment model established in the Step 2 is solved by the traditional optimal power flow algorithms, to obtain the optimal load curtailments f_{LC_s} of the system states s in the Step 1, and a new COLM-set is established based on this system state.

The specific method is as follows: the optimal load curtailment model (1) established by the system state s is solved by the traditional optimization calculating method, and the optimal load curtailment f_{LC_s} of the system state s is obtained. Meanwhile, the optimal solution x* can be divided into basic variable X_{B} and non-basic variable X_{N}, so the model (1) can be expressed as:

$$\begin{matrix}min & [ \begin{matrix}{c}_{B} \\ {c}_{N}\end{matrix} ] [ \begin{matrix}{x}_{B} \\ {x}_{N}\end{matrix} ] \\ s . t . & [ \begin{matrix}B & N\end{matrix} ] [ \begin{matrix}{x}_{B} \\ {x}_{N}\end{matrix} ] = b , {x}^{*} \geq 0\end{matrix} \qquad ( 10 )$$

where the optimal basis B and the non-optimal basis N correspond to the optimal basic variable X_{B} and the non-optimal basic variable X_{N}, respectively. Similarly, the cost coefficient vector c and the optimal solution x* in the model (1) are expressed as [C_{B}, C_{N}] and [X_{B}, X_{N}]^{T}, respectively.

Further, the equality constraint Ax=b can be expressed as:

$${Bx}_{B} + {Nx}_{N} = b \qquad ( 11 )$$

where the non-basic variable X_{N} is zero and the optimal basis B is invertible, the solution of the model (1) can be expressed as:

$$\begin{matrix}min & {f}_{LC \_ s} = {c}_{B}^{T} {B}^{- 1} b \\ s . t . & {x}_{B} = {B}^{- 1} b , {x}^{*} \geq 0\end{matrix} \qquad ( 12 )$$

Where f_{LC_s} is an objective function value corresponding to the optimal solution X*, that is, the optimal load curtailment f_{LC_s} of the system state s.

The Lagrange multiplier λₛ in the model (1) of the system state s is:

$${λ}_{s} = {c}_{B}^{T} {B}^{- 1} \qquad ( 13 )$$

The optimal basis B, the optimal basic variable X_{B}, the cost coefficient C_{B} corresponding to the optimal basis, the coefficient matrix A, the Lagrange multiplier λ and the right-hand-side vector b, which are obtained from the solving process of the optimal load curtailment model, are stored to establish a COLM-set in which all the system states have the same Lagrange multiplier λₛ. This COLM-set will be used in the Step 3 of the optimal load curtailment calculating method based on Lagrange multiplier.

Step 4B: the optimal load curtailment f_{LC_s} of the system state s from the Step 1 is calculated based on the Lagrange multiplier As determined in Step 3:

$${f}_{LC \_ s} = {λ}_{s} b \qquad ( 14 )$$

where the vector b can be determined according to the optimal load curtailment model established in the Step 2.

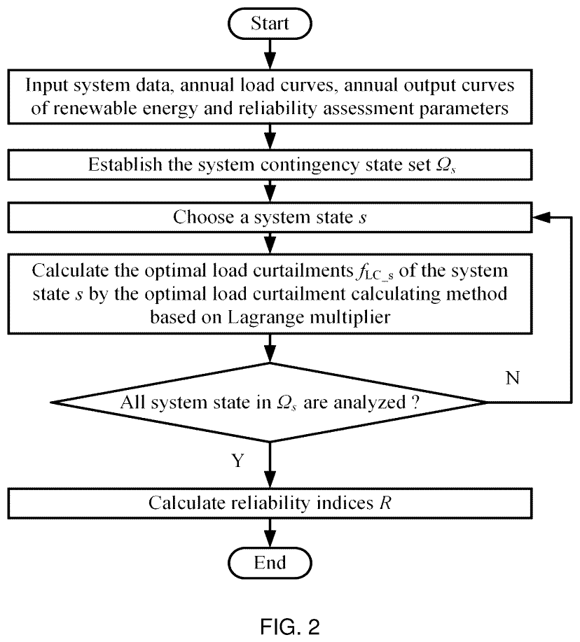

An application of the optimal load curtailment calculating method based on Lagrange multiplier in power system reliability assessment is provided, as shown in FIG. 2. Specifically, the optimal load curtailment calculating method based on Lagrange multiplier is applied in power system reliability assessment to establish a power system reliability assessment device which includes an input and initialization module, a system state selection module, a state impact analysis module and a reliability indices calculation module.
Module A. the input and initialization module is configured to input power system data, component reliability data, and preset parameters of reliability assessment methods, including topological structure, branch parameters, component parameters, load data, renewable generations locations, renewable generations output data, reliability parameters of components.
Module B. the system state selection module is configured to select the system states to be analyzed for the reliability assessment, including component contingency state, load time sequence state, and renewable generation output time sequence state. The system state selection method specifically includes State Enumeration (SE) technique, Monte Carlo Simulation (MCS) method, and improved methods of the SE technique and the MCS method.
Module C. the state impact analysis module is configured to analyze the impact of the system states selected by Module B. The present invention computes the impact of the contingency state by the optimal load curtailment calculating method based on Lagrange multiplier, and represents the impact using the load curtailments and all related indices.
Module D. the reliability indices calculation module is configured to compute the reliability indices of the power system based on the impact analysis results of the states.

The reliability index R is calculated by the following formula:

$$R = {\sum }_{s ∈ Ω} I ( s ) P ( s ) \qquad ( 15 )$$

where I(s) is an impact function of the state s, such as load curtailment; and Ω is a set of system states.

In the SE technique and its related approaches, the probability P(s) of the system state s is:

$$P ( s ) = {\prod }_{i = 1}^{{N}_{f}} {u}_{i} {\prod }_{j = 1}^{N - {N}_{f}} {a}_{j} \qquad ( 16 )$$

where N_{f} is the number of failed components in the system state s.

In the MCS method and its related calculating methods, the sampling frequency P(s) of the system state s can be expressed as:

$$P ( s ) = \frac{m ( s )}{M} \qquad ( 17 )$$

where M is the total number of samples, and m(s) is the number of occurrences of system state s.

The reliability index is determined by the corresponding state impact function I(s), and the common reliability indices include: probability of load curtailments (PLC), expected energy not supplied, (EENS), average duration of load curtailments (ADLC), and Average Interruption Duration Index (ASAI), PLC and EENS are often used in practice as reliability indices which are obtained from formula (15):

$$EENS = T {\sum }_{s ∈ Ω} {I}_{LC} ( s ) P ( s ) \qquad ( 18 )$$

$$PLC = {\sum }_{s ∈ Ω} {I}_{LCF} ( s ) P ( s ) \qquad ( 19 )$$

where T is the assessment period; I_{LC}(s) is the load curtailments of the system state s; and I_{LCF}(s) is:

$${I}_{L C F} ( s ) = \{ \begin{matrix}1 , & {I}_{LC} ( s ) > 0 \\ 0 , & {I}_{LC} ( s ) = 0\end{matrix} \qquad ( 20 )$$

In the Impact-increment-based State Enumeration Technique (IISE), the reliability index R is calculated by the following formula:

$$R = {\sum }_{k = 0}^{N} {\sum }_{s ∈ {Ω}_{s}^{k}} Δ {P}_{s} Δ {I}_{s} \qquad ( 21 )$$

where N is the total order of reliability assessment; and k is the fault order of the system state s.

The impact increment ΔIₛ of the system state s is:

$$Δ {I}_{s} = {\sum }_{k = 0}^{{n}_{s}} {( - 1 )}^{{n}_{s} - k} {\sum }_{ν ∈ {Ω}_{s}^{k}} {I}_{ν} \qquad ( 22 )$$

where nₛ is the number of failure components of the system state s; Ωₛ is the total sets of contingency states within nₛ-order of the system state s; and Ωₛ^{k} is a k-order subset of Ωₛ:

$$\{ \begin{matrix}{Ω}_{s} = \{ v \vert v ⊂ s , Card ( v ) = 0 , 1 , 2 , … , {n}_{s} \} \\ {Ω}_{s}^{k} = \{ v \vert v ⊂ s , Card ( v ) = k \} \\ {Ω}_{s}^{k} ⊆ {Ω}_{s}\end{matrix} \qquad ( 23 )$$

where Card(v) represents the number of failure components in the state v. If k=0, Ωₛ^{k}=ϕ.

The probability of impact increments ΔPₛ of the system state s is:

$$Δ {P}_{s} = {Π}_{i ∈ {Φ}_{s}} {u}_{i} \qquad ( 24 )$$

where Φs is a set of failure components in the system state s, and ΔPₛ=0 if the system state s is a non-fault state.

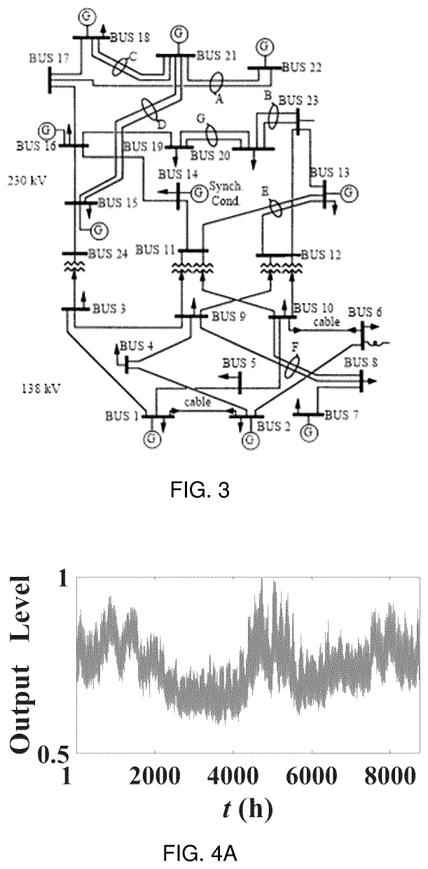

For the embodiment of the present invention, the RTS79 system is used as an example, and its system topology diagram is shown in FIG. 3. The test system includes 24 buses, 33 generator units and 38 branches. The total generation capacity and the load are 34.05 MW and 28.5 MW, respectively. The computer hardware configuration of the embodiment includes Intel Xeon Platinum 8180 CPU(ES) 28x1.8 GHz and 128 GB RAM. The operating system is Windows 10, and the simulation software is MATLAB2018a.

Three test scenarios are considered to highlight the applicability of the present invention.

Scenario 1 (S1): a unified load curve, and conventional generators; Scenario 2 (S2): three types of load curves, and conventional generators;

Scenario 3 (S3): three types of load curves, conventional generators, photovoltaics (PV) and wind turbines (WT);

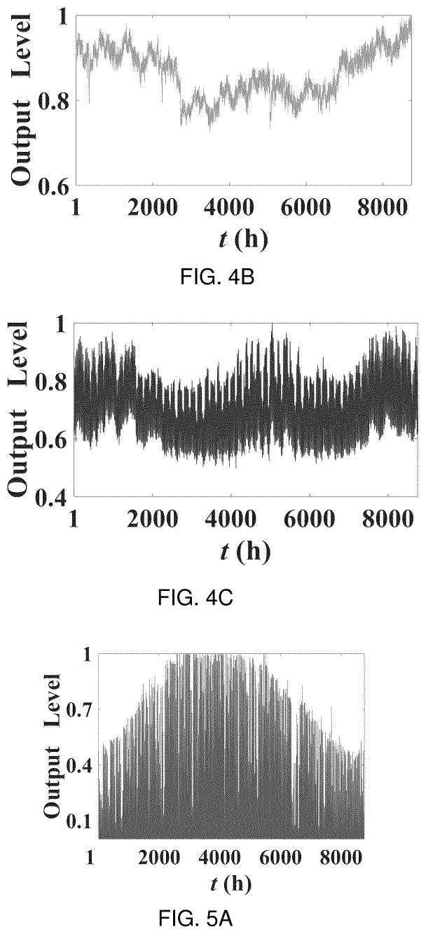

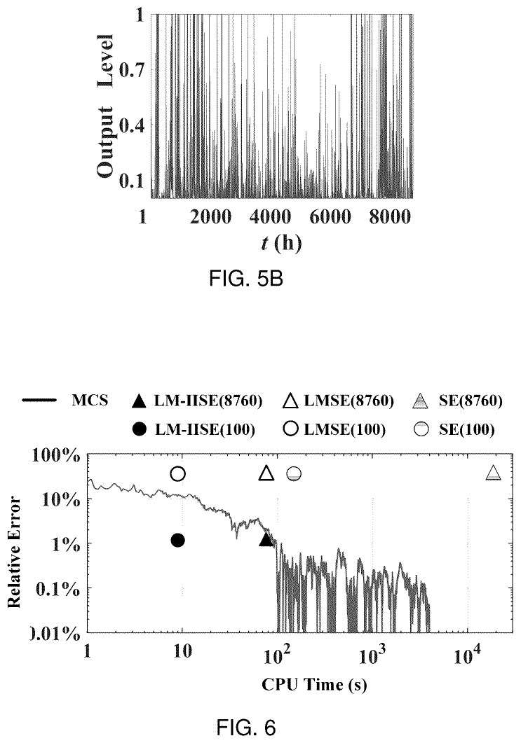

The unified load curve is calculated proportionally by three annual load curves (LA, LB, LC) according to the load proportion. The three annual load curves are the actual load curves of the northeast region, Edmonton region, and southern region of Alberta, Canada, as shown in FIGS. 4A-4B. The annual output curves of PV and WT are obtained from National Wind Technology Center (NREL), as shown in FIGS. 5A-5B. The node load types and renewable energy node settings in scenarios 2 and 3 are shown in Table 1.

TABLE 1
Node Settings of Scenarios 2 and 3
(RTS79)

| Type | Node |
|---|---|
| LA | 1, 2, 4, 5, 6, 7, 8 |
| LB | 15, 16, 18, 19, 20 |
| LC | 3, 9, 10, 13, 14 |
| PV | 13 |
| WT | 7 |

In the embodiment of the present invention, an optimal load curtailment calculating method based on Lagrange multiplier is applied in the reliability assessment to evaluate the reliability level of composite generation and transmission systems. The reliability index is EENS and the DC model is adopted as the optimal load curtailment model. Combined with the impact increment technique and clustering method, the proposed method is compared with the traditional SE technique and MCS method to verify the efficiency, accuracy and compatibility.

The input system includes node types, active loads, reference voltage, and upper and lower limits of the voltage of the RTS79 system; location, upper and lower limits of the active power output of generators; node topological relation, reactance, and power flow limits of the branches, as shown in Table 5. The three annual load curves and annual output curves of PV and WT are shown in FIGS. 4A-4C and 5A-5B.

According to the above steps of the present invention, different methods are adopted to assess the reliability of power systems in the three scenarios. For the MCS method, the sampled system state number is 5×10⁷, and the results of MCS are treated as a benchmark to evaluate other methods. The results are shown in Table 2.

TABLE 2
Reliability Assessment Results of Four Methods (RTS79)

| | | | | EENS | Average | |
|---|---|---|---|---|---|---|
| | | Number of | EENS | Relative | Number of | CPUTime |
| Scenario | Method | Clusters | (MWh/y) | Error (%) | COLM-sets | (s) |
| S1 | MCS | 8760 | 4105.29 | 0 | — | 3451 |
| | LM-IISE | 8760 | 4155.16 | 1.21 | 1.77 | 83 |
| | LMSE | | 2203.35 | 46.33 | — | 83 |
| | SE | | 2203.35 | 46.33 | — | 21746 |
| | LM-IISE | 100 | 4153.84 | 1.18 | 1.66 | 9 |
| | LMSE | | 2202.61 | 46.35 | — | 9 |
| | SE | | 2202.62 | 46.35 | — | 237 |
| | LM-IISE | 10 | 3989.10 | 2.83 | 1.39 | 7 |
| | LMSE | | 2125.43 | 48.2270 | — | 7 |
| | SE | | 2125.43 | 48.2270 | — | 25 |
| S2 | MCS | 8760 | 4131.43 | 0 | — | 3366 |
| | LM-IISE | 8760 | 4250.96 | 2.89 | 1.49 | 143 |
| | LMSE | | 2259.71 | 45.30 | — | 143 |
| | SE | | 2259.71 | 45.30 | — | 21908 |
| | LM-IISE | 100 | 4144.41 | 0.31 | 1.32 | 8 |
| | LMSE | | 2205.55 | 46.62 | — | 8 |
| | SE | | 2205.55 | 46.62 | — | 236 |
| | LM-IISE | 10 | 3787.41 | 8.33 | 1.15 | 7 |
| | LMSE | | 2000.11 | 51.59 | — | 7 |
| | SE | | 2000.11 | 51.59 | — | 25 |
| S3 | MCS | 8760 | 3566.93 | 0 | — | 3851 |
| | LM-IISE | 8760 | 3599.31 | 0.91 | 2.25 | 209 |
| | LMSE | | 1894.53 | 46.89 | — | 209 |
| | SE | | 1894.53 | 46.89 | — | 21869 |
| | LM-IISE | 500 | 3437.33 | 3.63 | 1.97 | 12 |
| | LMSE | | 1802.63 | 49.46 | — | 12 |
| | SE | | 1802.62 | 49.46 | — | 1216 |
| | LM-IISE | 100 | 3190.06 | 10.57 | 1.78 | 21 |
| | LMSE | | 1659.17 | 53.4846 | — | 21 |
| | SE | | 1659.17 | 53.4846 | — | 241 |

Table 2 shows the reliability assessment results by EENS. It can be seen that the optimal load curtailment based on Lagrange multiplier has an outstanding advantage in the calculation speed which is more than 10 times faster than that of the traditional SE technique. It can be seen from the average number of COLM-sets that the step 4B is performed about twice in the entire solving process (i.e., the optimal power flow problem is solved only twice), and other states are solved by Lagrange multiplier. As a result, the present invention saves a lot of calculation time. Owing to the compatibility of the present invention, the optimal load curtailment calculating method based on Lagrange multiplier can be combined with the IISE method (LM-IISE). In terms of calculation accuracy, the relative error of LM-IISE is less than 3%, which is close to the accuracy of the MCS method, so that the proposed method can satisfy the requirements of practical application. In conclusion, combined with the IISE technique and the clustering algorithm, the present invention can achieve an error less than 4% within 10 seconds, which is far superior to the other three methods in terms of both speed and accuracy.

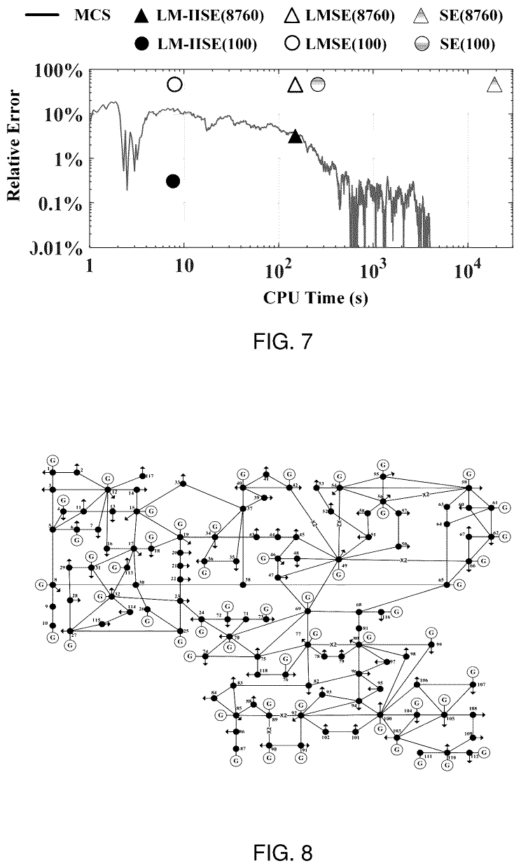

FIGS. 6 and 7 show the comparisons of the relative errors of reliability indices by the four methods for the RTS-79 system in the scenarios 1 and 2, respectively. In the figures, the closer to the lower-left corner the position of the method is, the more effective the method is. As shown in FIGS. 6 and 7, the computation speed of the method can be increased by more than 10 times, and the calculation accuracy remains unchanged. By integrating with the IISE technique and the clustering method, the position of LM-IISE (100) is located at the lower left of others. It can be seen from the relative error convergence curve that the MCS method spends more than 100 seconds when its relative error drops to 1%, while such precision can be reached by the method within 10 seconds.

Therefore, the optimal load curtailment method based on Lagrange multiplier according to the present invention has an outstanding advantage in the calculation speed, and the application thereof in traditional reliability assessment methods can achieve higher accuracy and efficiency than those of the traditional reliability assessment methods.

The implementation process and practical effects of the present invention are illustrated by another embodiment. The IEEE 118-bus system is tested in this embodiment, and its system topology diagram is shown in FIG. 8. The test system includes 118 buses, 54 generator units, 186 branches, 54 generation buses, and 64 load buses. The total generation capacity and the load are 9,966 MW and 4,242 MW, respectively. The node load types and renewable energy node settings in the scenarios 2 and 3 are shown in Table 3. The system configuration and test scenario settings are the same as those of the previous embodiment.

In the embodiment of the present invention, an optimal load curtailment calculating method based on Lagrange multiplier is applied in reliability assessment to evaluate the reliability level of composite generation and transmission system. The reliability index is EENS, and the DC model is adopted as the optimal load curtailment model. Combined with the impact increment technique and clustering method, the proposed method is compared with the traditional SE technique and MCS method to verify the efficiency, accuracy, compatibility, and practicability in large-scale systems.

The input system includes node types, active loads, reference voltage, and upper and lower limits of voltage of the IEEE 118-bus system; location, upper and lower limits of the active output of generators; node topological relation, reactance, and power flow limits of the branches, as shown in Table 6. The three annual load curves and annual output curves of PV and WT are shown in FIGS. 4A-4C and 5A-5B.

TABLE 3
Node Settings of Scenarios 2 and 3 (IEEE118-bus)

| Type | Node |
|---|---|
| LA | 82, 83, 84, 85, 86, 87, 88, 89, 90, 91, 92, 93, 94, 95, 96, 100, |
| | 101, 102, 103, 104, 105, 106, 107, 108, 109, 110, 111, 112 |
| LB | 1, 2, 3, 4, 5, 6, 7, 8, 9, 10, 11, 12, 13, 14, 15, 16, 17, 18, 19, |
| | 20, 21, 22, 23, 24, 25, 26, 27, 28, 29, 30, 31, 32, 70, 71, 72, |
| | 73, 74, 75, 113, 114, 115, 117 |
| LC | 33, 34, 35, 36, 37, 38, 39, 40, 41, 42, 43, 44, 45, 46, 47, 48, |
| | 49, 50, 51, 52, 53, 54, 55, 56, 57, 58, 59, 60, 61, 62, 63, 64, |
| | 65, 66, 67, 68, 69, 76, 77, 78, 79, 80, 81, 97, 98, 99, 116, 118 |
| PV | 1, 12, 25, 34, 49, 61, 70, 77, 90, 103, 111 |
| power | |
| Wind | 6, 18, 27, 40, 55, 65, 73, 85, 92, 105, 113 |
| power | |

According to the above steps of the present invention, different methods are adopted to assess the reliability of power systems in the three scenarios. For the MCS method, the sampled system state number is 108, and the results of MCS are treated as a benchmark to evaluate other methods. The results are shown in Table 4.

Table 4 shows the reliability assessment results by EENS. It can be seen that the optimal load curtailment based on Lagrange multiplier has an outstanding advantage in the calculation speed. When the number of clusters is greater than 100, the calculation speed of the present invention is more than 10 times faster than that of the traditional SE technique. It can be seen from the average number of COLM-sets that the step 4B is performed about five times in the entire solving process, (i.e., the optimal power flow problems are solved only five times), and other states are solved by Lagrange multiplier. As a result, it can save a lot of calculation time. Owing to the compatibility of the present invention, the optimal load curtailment calculating method based on Lagrange multiplier can be combined with the IISE method (LM-IISE). In terms of calculation accuracy, the relative error of LM-IISE is less than 5%, which is close to the accuracy of the MCS method, so that the proposed method can satisfy the requirements of practical application. In conclusion, combined with the IISE technique and the clustering algorithm, the present invention can achieve an error of about 5% within 100 seconds, which is far superior to the other three methods in terms of both speed and accuracy.

TABLE 4
Reliability Assessment Results of Four Methods (IEEE118-bus)

| | | | | EENS | Average | |
|---|---|---|---|---|---|---|
| | | Number of | EENS | Relative | Number of | CPU |
| Scenario | Method | clusters | (MWh/y) | Error (%) | COLM-sets | time (s) |
| S1 | MCS | — | 257.39 | 0 | — | 24831 |
| | LM-IISE | 8760 | 249.93 | 2.90 | 2.55 | 399 |
| | LMSE | | 170.86 | 33.62 | — | 399 |
| | SE | | 170.86 | 33.62 | — | 65031 |
| | LM-IISE | 100 | 249.92 | 2.90 | 2.43 | 62 |
| | LMSE | | 170.86 | 33.62 | — | 62 |
| | SE | | 170.86 | 33.62 | — | 747 |
| | LM-IISE | 10 | 243.81 | 5.27 | 2.15 | 50 |
| | LMSE | | 166.14 | 35.45 | — | 50 |
| | SE | | 166.14 | 35.45 | — | 77 |
| S2 | MCS | — | 243.04 | 0 | — | 24802 |
| | LM-IISE | 8760 | 237.91 | 2.11 | 4.97 | 588 |
| | LMSE | | 165.12 | 32.06 | — | 588 |
| | SE | | 165.12 | 32.06 | — | 64910 |
| | LM-IISE | | 233.02 | 4.12 | 3.98 | 98 |
| | LMSE | 100 | 161.66 | 33.48 | — | 98 |
| | SE | | 161.67 | 33.48 | — | 604 |
| | LM-IISE | | 209.67 | 13.73 | 2.82 | 67 |
| | LMSE | 10 | 145.47 | 40.15 | — | 67 |
| | SE | | 145.47 | 40.15 | — | 63 |
| S3 | MCS | — | 240.06 | 0 | — | 26946 |
| | LM-IISE | | 234.05 | 2.50 | 4.20 | 768 |
| | LMSE | 8760 | 162.95 | 32.12 | — | 768 |
| | SE | | 162.95 | 32.12 | — | 65219 |
| | LM-IISE | | 225.94 | 5.88 | 3.38 | 113 |
| | LMSE | 500 | 157.24 | 34.50 | — | 113 |
| | SE | | 157.24 | 34.50 | — | 3694 |
| | LM-IISE | | 214.11 | 10.81 | 2.73 | 73 |
| | LMSE | 100 | 149.36 | 37.78 | — | 73 |
| | SE | | 149.36 | 37.78 | — | 734 |

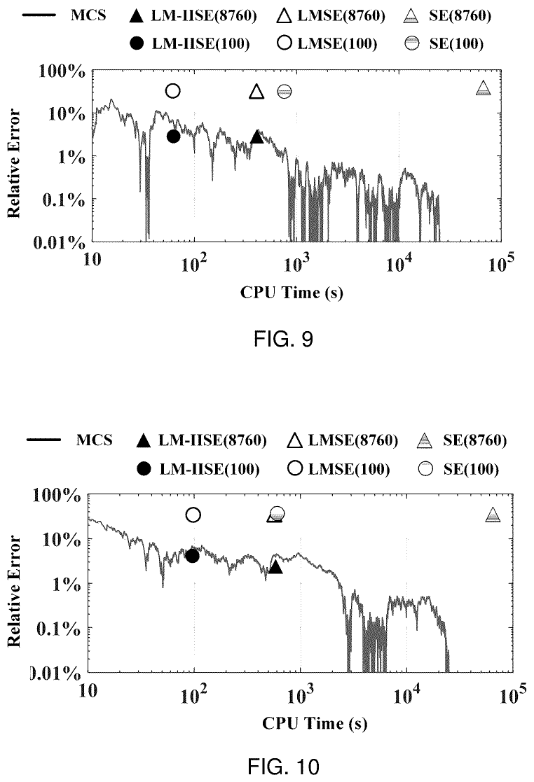

FIGS. 9 and 10 show the comparison of the relative errors reliability indices by the four methods for the IEEE118-bus system in the scenarios 1 and 2, respectively. In the figures, the closer to the lower-left corner the position of the method is, the more effective the method is. As shown in the FIGS. 9 and 10, the computation speed of the method can be increased by more than 10 times, and the calculation accuracy remains unchanged. By integrating with the IISE technique and the clustering method, the position of LM-IISE (100) is located at the lower left of others. It can be seen from the relative error convergence curve that the present invention is slightly superior to the MCS method. This is because that the SE technique is not suitable for large-scale system reliability assessment. We would achieve a better performance if the present invention is applied in the MCS method.

Therefore, the optimal load curtailment method based on Lagrange multiplier has an outstanding advantage in the calculation speed, and the application thereof in traditional reliability assessment methods can achieve higher accuracy and efficiency than those of the traditional reliability assessment methods.

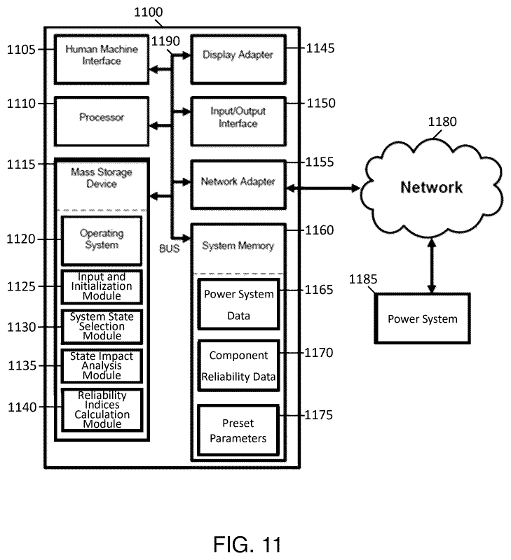

Referring to FIG. 11, the methods and systems of the present disclosure can be implemented on power system reliability assessment device 1100, including one or more computers. The methods and systems disclosed can utilize one or more computers to perform one or more functions in one or more locations. The processing of the disclosed methods and systems can also be performed by software components stored on, for example, without limitation, mass storage device 1115. The disclosed systems and methods can be described in the general context of computer-executable instructions such as program modules including one or more of, Input and Initialization Module 1125, System State Selection Module 1130, State Impact Analysis Module 1135, Reliability Indices Calculation Module 1140, etc. being executed on processor 1110 of power system reliability assessment device 1100. Input and Initialization Module 1125 is configured to input power system data 1165, component reliability data 1170, and preset parameters 1175 of reliability assessment methods, including topological structure, branch parameters, component parameters, load data, renewable generation locations, renewable generation output data, and reliability parameters of components. System State Selection Module 1130 is configured to select the system states to be analyzed for the reliability assessment, including component contingency state, load time sequence state, and renewable generation output time sequence state. State Impact Analysis Module 1135 is configured to analyze the impact of the system states selected by the module B using the optimal load curtailment calculating method of Lagrange multiplier according to claim 1, and represents the impact by the load curtailments and all related indices. Reliability Indices Calculation Module 1140 is configured to compute the reliability indices of the power system based on the impact analysis results of the system states. These program modules can be stored on mass storage device 1115 of power system reliability assessment device 1100 co-located with power system 1185 or remotely located respect to power system 1185. Each of the operating modules can comprise elements of the programming and the data management software.

Program code for an optimal load curtailment calculating method based on a Lagrange multiplier may be stored on one or more of mass storage device 1115 and system memory 1160 that, when executed by processor 1110 cause processor 1110 to carry out steps 1-3, as described with reference to FIG. 1 above.

The components of power system reliability assessment device 1100 include, but are not limited to, one or more processors or processing units 1110, system memory 1160, mass storage device 1115, operating system 1120, system memory 1160, display adapter 1145, Input/Output Interface 1150, network adaptor 1155, and system bus 1190 that couples various system components. Power system reliability assessment device 1100 and power system 1185 may communicate via wired or wireless network 1180 at physically separate locations as a fully distributed system, or power system reliability assessment device 1100 may be integrated into power system 1185. By way of example, power system reliability assessment device 1100 may be a personal computer, a portable computer, a smart device, a network computer, a peer device, or other common network node, and so on. Logical connections between one or more computers and one or more power systems can be made via network 1180, such as a local area network (LAN) and/or a general wide area network (WAN).

The application of the optimal load curtailment calculating method based on Lagrange multiplier in power system reliability assessment in the present disclosure can be implemented in such a way that the processor executing the method is integrated as a part of a specialized controller with the power system reliability assessment service, and then the power system uses the specialized controller to control the power system by using the data from the power system reliability assessment device, for example, to reduce power consumption.

The power system reliability assessment device includes the input and initialization module, the system state selection module, the state impact analysis module and the reliability indices calculation module. The power system reliability assessment device further includes sensors and instruments that measure and analyze electrical power and its characteristics. Specifically, the power system reliability assessment device includes current transducers that measure the electrical current flowing through a circuit; voltage sensors that measure the electrical potential difference; power analyzers that provide comprehensive measurements of power; and energy monitors that measure and track energy consumption over time; and the specialized controller that uses that information to automatically or remotely control the power flow to various electrical loads. This combination helps identify inefficiencies and takes action to correct them

The specialized controller is a controller designed for a large-scale power system to ensure grid code compliance and manage multiple power sources. The specialized controller includes a processor embedded with the optimal load curtailment calculating method.

The applications of the present disclosure can be implemented in various fields. The present disclosure can help to maintain gird stability, control voltage, optimize the power plant, and monitor conditions, control motor, and control distributed energy. For the grid stability, the power controller uses real-time data from the assessment device to maintain grid stability, which is challenged by the intermittency of renewable energy sources. The controller can adjust the output of renewable energy generators or other devices to compensate for fluctuations. For the voltage control, the controller assesses the impact of distributed energy resources and manages voltage regulators to prevent over or undervoltage issues. For the power plant optimization, the controller manages renewable power plants to ensure optimal operation, especially during changes in system configuration; for monitoring, the controller can perform predictive maintenance based on electrical readings; for motor control, the controller can use power assessment data to optimize the performance of electric motors, ensuring the motors operate efficiently and safely.

It should be understood by those of skills in the art that the drawings and tables are merely schematic diagrams of a preferred embodiment, and the order of the above embodiments in the present invention is only for description, and not meant to the superiority and inferiority of the embodiments.

The proposes, technical solutions and beneficial effects of the present invention are further described in detail by the embodiments mentioned above. It should be understood that those described above are merely preferred embodiments of the present invention, and are not intended to limit the protection scope of the present invention. Any modifications, equivalent substitutions and improvements made within the spirit and principle of the present invention shall fall into the protection scope of the present invention.

TABLE 5A
Bus Data of RTS79 System

| | Active |
|---|---|
| Bus | load |
| Number | (MW) |
| 1 | 108 |
| 2 | 97 |
| 3 | 180 |
| 4 | 74 |
| 5 | 71 |
| 6 | 136 |
| 7 | 125 |
| 8 | 171 |
| 9 | 175 |
| 10 | 195 |
| 11 | 0 |
| 12 | 0 |
| 13 | 265 |
| 14 | 194 |
| 15 | 317 |
| 16 | 100 |
| 17 | 0 |
| 18 | 333 |
| 19 | 181 |
| 20 | 128 |
| 21 | 0 |
| 22 | 0 |
| 23 | 0 |
| 24 | 0 |

TABLE 5B
Generator Data of RTS79 System

| | Maximum | |
|---|---|---|
| | Active | |
| | Power | |
| Bus | Output | Unavailability |
| Number | (MW) | (%) |
| 1 | 20 | 10 |
| 1 | 20 | 10 |
| 1 | 76 | 2 |
| 1 | 76 | 2 |
| 2 | 20 | 10 |
| 2 | 20 | 10 |
| 2 | 76 | 2 |
| 2 | 76 | 2 |
| 7 | 100 | 4 |
| 7 | 100 | 4 |
| 7 | 100 | 4 |
| 13 | 197 | 5 |
| 13 | 197 | 5 |
| 13 | 197 | 5 |
| 14 | 0 | 0 |
| 15 | 12 | 2 |
| 15 | 12 | 2 |
| 15 | 12 | 2 |
| 15 | 12 | 2 |
| 15 | 12 | 2 |
| 15 | 155 | 4 |
| 16 | 155 | 4 |
| 18 | 400 | 12 |
| 21 | 400 | 12 |
| 22 | 50 | 1 |
| 22 | 50 | 1 |
| 22 | 50 | 1 |
| 22 | 50 | 1 |
| 22 | 50 | 1 |
| 22 | 50 | 1 |
| 23 | 155 | 4 |
| 23 | 155 | 4 |
| 23 | 350 | 8 |

TABLE 5C
Branch Data of RTS79 System

| “From” | “To” | | Transformer | Transmission | |
|---|---|---|---|---|---|
| Bus | Bus | Reactance | Ratio | Limit | Unavailability |
| Number | Number | (p.u.) | (p.u.) | (MW) | (%) |
| 1 | 2 | 0.0139 | | 175 | 0.04382 |
| 1 | 3 | 0.2112 | | 175 | 0.05819 |
| 1 | 5 | 0.0845 | | 175 | 0.03766 |
| 2 | 4 | 0.1267 | | 175 | 0.04450 |
| 2 | 6 | 0.1920 | | 175 | 0.05476 |
| 3 | 9 | 0.1190 | | 175 | 0.04336 |
| 3 | 24 | 0.0839 | 1.03 | 400 | 0.17504 |
| 4 | 9 | 0.1037 | | 175 | 0.04108 |
| 5 | 10 | 0.0883 | | 175 | 0.03880 |
| 6 | 10 | 0.0605 | | 175 | 0.13168 |
| 7 | 8 | 0.0614 | | 175 | 0.03423 |
| 8 | 9 | 0.1651 | | 175 | 0.05020 |
| 8 | 10 | 0.1651 | | 175 | 0.05020 |
| 9 | 11 | 0.0839 | 1.03 | 400 | 0.17504 |
| 9 | 12 | 0.0839 | 1.03 | 400 | 0.17504 |
| 10 | 11 | 0.0839 | 1.02 | 400 | 0.17504 |
| 10 | 12 | 0.0839 | 1.02 | 400 | 0.17504 |
| 11 | 13 | 0.0476 | | 500 | 0.05020 |
| 11 | 14 | 0.0418 | | 500 | 0.04895 |
| 12 | 13 | 0.0476 | | 500 | 0.05020 |
| 12 | 23 | 0.0966 | | 500 | 0.06525 |
| 13 | 23 | 0.0865 | | 500 | 0.06149 |
| 14 | 16 | 0.0389 | | 500 | 0.04769 |
| 15 | 16 | 0.0173 | | 500 | 0.04142 |
| 15 | 21 | 0.0490 | | 500 | 0.05146 |
| 15 | 21 | 0.0490 | | 500 | 0.05146 |
| 15 | 24 | 0.0519 | | 500 | 0.05146 |
| 16 | 17 | 0.0259 | | 500 | 0.04393 |
| 16 | 19 | 0.0231 | | 500 | 0.04268 |
| 17 | 18 | 0.0144 | | 500 | 0.04017 |
| 17 | 22 | 0.1053 | | 500 | 0.06776 |
| 18 | 21 | 0.0259 | 0.96 | 500 | 0.04393 |
| 18 | 21 | 0.0259 | | 500 | 0.04393 |
| 19 | 20 | 0.0396 | | 500 | 0.04769 |
| 19 | 20 | 0.0396 | | 500 | 0.04769 |
| 20 | 23 | 0.0216 | 0.96 | 500 | 0.04268 |
| 20 | 23 | 0.0216 | | 500 | 0.04268 |
| 21 | 22 | 0.0678 | | 500 | 0.05647 |

TABLE 6A
Bus Data of IEEE 118-bus System

| | Active |
|---|---|
| Bus | load |
| Number | (MW) |
| 1 | 51 |
| 2 | 20 |
| 3 | 39 |
| 4 | 39 |
| 5 | 0 |
| 6 | 52 |
| 7 | 19 |
| 8 | 28 |
| 9 | 0 |
| 10 | 0 |
| 11 | 70 |
| 12 | 47 |
| 13 | 34 |
| 14 | 14 |
| 15 | 90 |
| 16 | 25 |
| 17 | 11 |
| 18 | 60 |
| 19 | 45 |
| 20 | 18 |
| 21 | 14 |
| 22 | 10 |
| 23 | 7 |
| 24 | 13 |
| 25 | 0 |
| 26 | 0 |
| 27 | 71 |
| 28 | 17 |
| 29 | 24 |
| 30 | 0 |
| 31 | 43 |
| 32 | 59 |
| 33 | 23 |
| 34 | 59 |
| 35 | 33 |
| 36 | 31 |
| 37 | 0 |
| 38 | 0 |
| 39 | 27 |
| 40 | 66 |
| 41 | 37 |
| 42 | 96 |
| 43 | 18 |
| 44 | 16 |
| 45 | 53 |
| 46 | 28 |
| 47 | 34 |
| 48 | 20 |
| 49 | 87 |
| 50 | 17 |
| 51 | 17 |
| 52 | 18 |
| 53 | 23 |
| 54 | 113 |
| 55 | 63 |
| 56 | 84 |
| 57 | 12 |
| 58 | 12 |
| 59 | 277 |
| 60 | 78 |
| 61 | 0 |
| 62 | 77 |
| 63 | 0 |
| 64 | 0 |
| 65 | 0 |
| 66 | 39 |
| 67 | 28 |
| 68 | 0 |
| 69 | 0 |
| 70 | 66 |
| 71 | 0 |
| 72 | 12 |
| 73 | 6 |
| 74 | 68 |
| 75 | 47 |
| 76 | 68 |
| 77 | 61 |
| 78 | 71 |
| 79 | 39 |
| 80 | 130 |
| 81 | 0 |
| 82 | 54 |
| 83 | 20 |
| 84 | 11 |
| 85 | 24 |
| 86 | 21 |
| 87 | 0 |
| 88 | 48 |
| 89 | 0 |
| 90 | 163 |
| 91 | 10 |
| 92 | 65 |
| 93 | 12 |
| 94 | 30 |
| 95 | 42 |
| 96 | 38 |
| 97 | 15 |
| 98 | 34 |
| 99 | 42 |
| 100 | 37 |
| 101 | 22 |
| 102 | 5 |
| 103 | 23 |
| 104 | 38 |
| 105 | 31 |
| 106 | 43 |
| 107 | 50 |
| 108 | 2 |
| 109 | 8 |
| 110 | 39 |
| 111 | 0 |
| 112 | 68 |
| 113 | 6 |
| 114 | 8 |
| 115 | 22 |
| 116 | 184 |
| 117 | 20 |
| 118 | 33 |

TABLE 6B
Generator Data of IEEE 118-bus System

| | Maximum | |
|---|---|---|
| | Active | |
| | Power | |
| Bus | output | Unavailability |
| Number | (MW) | (%) |
| 1 | 100 | 0.015 |
| 4 | 100 | 0.015 |
| 6 | 100 | 0.015 |
| 8 | 100 | 0.015 |
| 10 | 550 | 0.015 |
| 12 | 185 | 0.015 |
| 15 | 100 | 0.015 |
| 18 | 100 | 0.015 |
| 19 | 100 | 0.015 |
| 24 | 100 | 0.015 |
| 25 | 320 | 0.015 |
| 26 | 414 | 0.015 |
| 27 | 100 | 0.015 |
| 31 | 107 | 0.015 |
| 32 | 100 | 0.015 |
| 34 | 100 | 0.015 |
| 36 | 100 | 0.015 |
| 40 | 100 | 0.015 |
| 42 | 100 | 0.015 |
| 46 | 119 | 0.015 |
| 49 | 304 | 0.015 |
| 54 | 148 | 0.015 |
| 55 | 100 | 0.015 |
| 56 | 100 | 0.015 |
| 59 | 255 | 0.015 |
| 61 | 260 | 0.015 |
| 62 | 100 | 0.015 |
| 65 | 491 | 0.015 |
| 66 | 492 | 0.015 |
| 69 | 805.2 | 0.015 |
| 70 | 100 | 0.015 |
| 72 | 100 | 0.015 |
| 73 | 100 | 0.015 |
| 74 | 100 | 0.015 |
| 76 | 100 | 0.015 |
| 77 | 100 | 0.015 |
| 80 | 577 | 0.015 |
| 85 | 100 | 0.015 |
| 87 | 104 | 0.015 |
| 89 | 707 | 0.015 |
| 90 | 100 | 0.015 |
| 91 | 100 | 0.015 |
| 92 | 100 | 0.015 |
| 99 | 100 | 0.015 |
| 100 | 352 | 0.015 |
| 103 | 140 | 0.015 |
| 104 | 100 | 0.015 |
| 105 | 100 | 0.015 |
| 107 | 100 | 0.015 |
| 110 | 100 | 0.015 |
| 111 | 136 | 0.015 |
| 112 | 100 | 0.015 |
| 113 | 100 | 0.015 |
| 116 | 100 | 0.015 |

TABLE 6C
Branch Data of IEEE 118-bus System

| “From” | “To” | | Transformer | Transmission | Unavail- |
|---|---|---|---|---|---|
| Bus | Bus | Reactance | ratio | limit | ability |
| Number | Number | (p.u.) | (p.u.) | (MW) | (%) |
| 1 | 2 | 0.0999 | | 175 | 0.04153 |
| 1 | 3 | 0.0424 | | 175 | 0.03353 |
| 4 | 5 | 0.00798 | | 500 | 0.02874 |
| 3 | 5 | 0.108 | | 175 | 0.04265 |
| 5 | 6 | 0.054 | | 175 | 0.03514 |
| 6 | 7 | 0.0208 | | 175 | 0.03052 |
| 8 | 9 | 0.0305 | | 500 | 0.03187 |
| 8 | 5 | 0.0267 | 0.9850 | 500 | 0.18 |
| 9 | 10 | 0.0322 | | 500 | 0.03211 |
| 4 | 11 | 0.0688 | | 175 | 0.0372 |
| 5 | 11 | 0.0682 | | 175 | 0.03712 |
| 11 | 12 | 0.0196 | | 175 | 0.03036 |
| 2 | 12 | 0.0616 | | 175 | 0.0362 |
| 3 | 12 | 0.16 | | 175 | 0.04989 |
| 7 | 12 | 0.034 | | 175 | 0.03236 |
| 11 | 13 | 0.0731 | | 175 | 0.0378 |
| 12 | 14 | 0.0707 | | 175 | 0.03746 |
| 13 | 15 | 0.2444 | | 175 | 0.06163 |
| 14 | 15 | 0.195 | | 175 | 0.05475 |
| 12 | 16 | 0.0834 | | 175 | 0.03923 |
| 15 | 17 | 0.0437 | | 500 | 0.03371 |
| 16 | 17 | 0.1801 | | 175 | 0.05268 |
| 17 | 18 | 0.0505 | | 175 | 0.03465 |
| 18 | 19 | 0.0493 | | 175 | 0.03449 |
| 19 | 20 | 0.117 | | 175 | 0.0439 |
| 15 | 19 | 0.0394 | | 175 | 0.03311 |
| 20 | 21 | 0.0849 | | 175 | 0.03944 |
| 21 | 22 | 0.097 | | 175 | 0.04112 |
| 22 | 23 | 0.159 | | 175 | 0.04975 |
| 23 | 24 | 0.0492 | | 175 | 0.03447 |
| 23 | 25 | 0.08 | | 500 | 0.03876 |
| 26 | 25 | 0.0382 | 0.96 | 500 | 0.18 |
| 25 | 27 | 0.163 | | 500 | 0.0503 |
| 27 | 28 | 0.0855 | | 175 | 0.03952 |
| 28 | 29 | 0.0943 | | 175 | 0.04075 |
| 30 | 17 | 0.0388 | 0.96 | 500 | 0.18 |
| 8 | 30 | 0.0504 | | 175 | 0.03464 |
| 26 | 30 | 0.086 | | 500 | 0.03959 |
| 17 | 31 | 0.1563 | | 175 | 0.04937 |
| 29 | 31 | 0.0331 | | 175 | 0.03223 |
| 23 | 32 | 0.1153 | | 140 | 0.04367 |
| 31 | 32 | 0.0985 | | 175 | 0.04133 |
| 27 | 32 | 0.0755 | | 175 | 0.03813 |
| 15 | 33 | 0.1244 | | 175 | 0.04493 |
| 19 | 34 | 0.247 | | 175 | 0.06199 |
| 35 | 36 | 0.0102 | | 175 | 0.02905 |
| 35 | 37 | 0.0497 | | 175 | 0.03454 |
| 33 | 37 | 0.142 | | 175 | 0.04738 |
| 34 | 36 | 0.0268 | | 175 | 0.03136 |
| 34 | 37 | 0.0094 | | 500 | 0.02894 |
| 38 | 37 | 0.0375 | 0.935 | 500 | 0.18 |
| 37 | 39 | 0.106 | | 175 | 0.04237 |
| 37 | 40 | 0.168 | | 175 | 0.051 |
| 30 | 38 | 0.054 | | 175 | 0.03514 |
| 39 | 40 | 0.0605 | | 175 | 0.03605 |
| 40 | 41 | 0.0487 | | 175 | 0.0344 |
| 40 | 42 | 0.183 | | 175 | 0.05309 |
| 41 | 42 | 0.135 | | 175 | 0.04641 |
| 43 | 44 | 0.2454 | | 175 | 0.06177 |
| 34 | 43 | 0.1681 | | 175 | 0.05101 |
| 44 | 45 | 0.0901 | | 175 | 0.04016 |
| 45 | 46 | 0.1356 | | 175 | 0.04649 |
| 46 | 47 | 0.127 | | 175 | 0.0453 |
| 46 | 48 | 0.189 | | 175 | 0.05392 |
| 47 | 49 | 0.0625 | | 175 | 0.03632 |
| 42 | 49 | 0.323 | | 175 | 0.07256 |
| 42 | 49 | 0.323 | | 175 | 0.07256 |
| 45 | 49 | 0.186 | | 175 | 0.0535 |
| 48 | 49 | 0.0505 | | 175 | 0.03465 |
| 49 | 50 | 0.0752 | | 175 | 0.03809 |
| 49 | 51 | 0.137 | | 175 | 0.04669 |
| 51 | 52 | 0.0588 | | 175 | 0.03581 |
| 52 | 53 | 0.1635 | | 175 | 0.05037 |
| 53 | 54 | 0.122 | | 175 | 0.0446 |
| 49 | 54 | 0.289 | | 175 | 0.06783 |
| 49 | 54 | 0.291 | | 175 | 0.06811 |
| 54 | 55 | 0.0707 | | 175 | 0.03746 |
| 54 | 56 | 0.00955 | | 175 | 0.02896 |
| 55 | 56 | 0.0151 | | 175 | 0.02973 |
| 56 | 57 | 0.0966 | | 175 | 0.04107 |
| 50 | 57 | 0.134 | | 10 | 0.04627 |
| 56 | 58 | 0.0966 | | 175 | 0.04107 |
| 51 | 58 | 0.0719 | | 175 | 0.03763 |
| 54 | 59 | 0.2293 | | 175 | 0.05953 |
| 56 | 59 | 0.251 | | 175 | 0.06254 |
| 56 | 59 | 0.239 | | 175 | 0.06087 |
| 55 | 59 | 0.2158 | | 175 | 0.05765 |
| 59 | 60 | 0.145 | | 100 | 0.0478 |
| 59 | 61 | 0.15 | | 175 | 0.0485 |
| 60 | 61 | 0.0135 | | 50 | 0.02951 |
| 60 | 62 | 0.0561 | | 50 | 0.03543 |
| 61 | 62 | 0.0376 | | 175 | 0.03286 |
| 63 | 59 | 0.0386 | 0.96 | 500 | 0.18 |
| 63 | 64 | 0.02 | | 500 | 0.03041 |
| 64 | 61 | 0.0268 | 0.985 | 500 | 0.18 |
| 38 | 65 | 0.0986 | | 500 | 0.04135 |
| 64 | 65 | 0.0302 | | 500 | 0.03183 |
| 49 | 66 | 0.0919 | | 500 | 0.04041 |
| 49 | 66 | 0.0919 | | 500 | 0.04041 |
| 62 | 66 | 0.218 | | 175 | 0.05795 |
| 62 | 67 | 0.117 | | 175 | 0.0439 |
| 65 | 66 | 0.037 | 0.935 | 500 | 0.18 |
| 66 | 67 | 0.1015 | | 175 | 0.04175 |
| 65 | 68 | 0.016 | | 500 | 0.02986 |
| 47 | 69 | 0.2778 | | 175 | 0.06627 |
| 49 | 69 | 0.324 | | 175 | 0.0727 |
| 68 | 69 | 0.037 | 0.935 | 500 | 0.18 |
| 69 | 70 | 0.127 | | 500 | 0.0453 |
| 24 | 70 | 0.4115 | | 175 | 0.08487 |
| 70 | 71 | 0.0355 | | 175 | 0.03257 |
| 24 | 72 | 0.196 | | 175 | 0.05489 |
| 71 | 72 | 0.18 | | 175 | 0.05267 |
| 71 | 73 | 0.0454 | | 175 | 0.03395 |
| 70 | 74 | 0.1323 | | 175 | 0.04603 |
| 70 | 75 | 0.141 | | 175 | 0.04724 |
| 69 | 75 | 0.122 | | 500 | 0.0446 |
| 74 | 75 | 0.0406 | | 175 | 0.03328 |
| 76 | 77 | 0.148 | | 175 | 0.04822 |
| 69 | 77 | 0.101 | | 175 | 0.04168 |
| 75 | 77 | 0.1999 | | 175 | 0.05544 |
| 77 | 78 | 0.0124 | | 175 | 0.02935 |
| 78 | 79 | 0.0244 | | 175 | 0.03102 |
| 77 | 80 | 0.0485 | | 500 | 0.03438 |
| 77 | 80 | 0.105 | | 500 | 0.04224 |
| 79 | 80 | 0.0704 | | 175 | 0.03742 |
| 68 | 81 | 0.0202 | | 500 | 0.03044 |
| 81 | 80 | 0.037 | 0.935 | 500 | 0.18 |
| 77 | 82 | 0.0853 | | 200 | 0.0395 |
| 82 | 83 | 0.03665 | | 200 | 0.03273 |
| 83 | 84 | 0.132 | | 175 | 0.04599 |
| 83 | 85 | 0.148 | | 175 | 0.04822 |
| 84 | 85 | 0.0641 | | 175 | 0.03655 |
| 85 | 86 | 0.123 | | 500 | 0.04474 |
| 86 | 87 | 0.2074 | | 500 | 0.05648 |
| 85 | 88 | 0.102 | | 500 | 0.04182 |
| 85 | 89 | 0.173 | | 175 | 0.05169 |
| 88 | 89 | 0.0712 | | 500 | 0.03753 |
| 89 | 90 | 0.188 | | 500 | 0.05378 |
| 89 | 90 | 0.0997 | | 175 | 0.0415 |
| 90 | 91 | 0.0836 | | 175 | 0.03926 |
| 89 | 92 | 0.0505 | | 175 | 0.03465 |
| 89 | 92 | 0.1581 | | 175 | 0.04962 |
| 91 | 92 | 0.1272 | | 175 | 0.04532 |
| 92 | 93 | 0.0848 | | 175 | 0.03943 |
| 92 | 94 | 0.158 | | 175 | 0.04961 |
| 93 | 94 | 0.0732 | | 175 | 0.03781 |
| 94 | 95 | 0.0434 | | 175 | 0.03367 |
| 80 | 96 | 0.182 | | 175 | 0.05295 |
| 82 | 96 | 0.053 | | 175 | 0.035 |
| 94 | 96 | 0.0869 | | 175 | 0.03972 |
| 80 | 97 | 0.0934 | | 175 | 0.04062 |
| 80 | 98 | 0.108 | | 175 | 0.04265 |
| 80 | 99 | 0.206 | | 200 | 0.05628 |
| 92 | 100 | 0.295 | | 175 | 0.06866 |
| 94 | 100 | 0.058 | | 175 | 0.0357 |
| 95 | 96 | 0.0547 | | 175 | 0.03524 |
| 96 | 97 | 0.0885 | | 175 | 0.03994 |
| 98 | 100 | 0.179 | | 175 | 0.05253 |
| 99 | 100 | 0.0813 | | 175 | 0.03894 |
| 100 | 101 | 0.1262 | | 175 | 0.04518 |
| 92 | 102 | 0.0559 | | 175 | 0.03541 |
| 101 | 102 | 0.112 | | 175 | 0.04321 |
| 100 | 103 | 0.0525 | | 500 | 0.03493 |
| 100 | 104 | 0.204 | | 175 | 0.05601 |
| 103 | 104 | 0.1584 | | 175 | 0.04966 |
| 103 | 105 | 0.1625 | | 175 | 0.05023 |
| 100 | 106 | 0.229 | | 175 | 0.05948 |
| 104 | 105 | 0.0378 | | 175 | 0.03289 |
| 105 | 106 | 0.0547 | | 175 | 0.03524 |
| 105 | 107 | 0.183 | | 175 | 0.05309 |
| 105 | 108 | 0.0703 | | 175 | 0.03741 |
| 106 | 107 | 0.183 | | 175 | 0.05309 |
| 108 | 109 | 0.0288 | | 175 | 0.03164 |
| 103 | 110 | 0.1813 | | 175 | 0.05285 |
| 109 | 110 | 0.0762 | | 175 | 0.03823 |
| 110 | 111 | 0.0755 | | 175 | 0.03813 |
| 110 | 112 | 0.064 | | 175 | 0.03653 |
| 17 | 113 | 0.0301 | | 175 | 0.03182 |
| 32 | 113 | 0.203 | | 500 | 0.05587 |
| 32 | 114 | 0.0612 | | 175 | 0.03614 |
| 27 | 115 | 0.0741 | | 175 | 0.03794 |
| 114 | 115 | 0.0104 | | 175 | 0.02908 |
| 68 | 116 | 0.00405 | | 500 | 0.02819 |
| 12 | 117 | 0.14 | | 175 | 0.0471 |
| 75 | 118 | 0.0481 | | 175 | 0.03432 |
| 76 | 118 | 0.0544 | | 175 | 0.0352 |

1. A method of an optimal load curtailment calculation based on Lagrange multiplier in power system reliability assessment, the method, when executed by a processor, causes the processor to carry out the steps, comprising:
Step 1: inputting all system states s collected by current transducers. voltage sensors, and power analyzers and energy monitors to be analyzed for reliability assessment, and establishing corresponding optimal load curtailment models, namely:
$$\begin{matrix}min & {c}^{T} x \\ s . t . & Ax = b , x \geq 0\end{matrix} \qquad ( 1 )$$
where x is a variable vector; A is a coefficient matrix; b is a right-hand-side vector;
c is a cost coefficient vector; wherein the current transducers measure the electrical current flowing through a circuit; voltage sensors measure the electrical potential difference; power analyzers provide comprehensive measurements of power; and energy monitors measure and track energy consumption over time;
Step 2: classifying the above optimal load curtailment models into several sets by the Lagrange multiplier λₛ; and
Step 3: solving all the optimal load curtailment models in each set by the Lagrange multiplier λₛ of the set, to obtain optimal load curtailments f_{LC_s} of the system states; wherein the Step 3 comprises a step as follows:
calculating the optimal load curtailments f_{LC_s} of the system states s by the Lagrange multiplier λₛ:
$${f}_{LC \_ s} = {λ}_{s} b \qquad ( 2 )$$
where b is determined by the optimal load curtailment model established in the Step 1;
wherein the Step 2 comprises the following steps:
comparing an unclassified optimal load curtailment model with a classified one, and the two models belong to the same set if the Lagrange multipliers of the two models are the same;
determining whether the Lagrange multipliers of the two optimal load curtailment models are the same comprises the following steps:
adopting judgment criteria to determine whether the different vectors A, b, and c of the two models will lead to different Lagrange multipliers As; wherein the judgment criteria are as follows:
\textcircled{1} If the difference occurs in a cost coefficient vector c, wherein c is a cost coefficient vector it is assumed that the model in the Step 2 is c+Δc, and the model corresponding to the system state to be compared with is the vector c; if formula (3) is met, the two system states belong to the same COLM-set:
$${( c + Δ c )}^{T} - {( {c}_{B} + Δ {c}_{B} )}^{T} {B}^{- 1} A \leq 0 \qquad ( 3 )$$
as the cost coefficient vector c is different, the Lagrange multiplier As of the system state s in the Step 1 is:
$${λ}_{s} = {( {c}_{B} + Δ {c}_{B} )}^{T} {B}^{- 1} \qquad ( 4 )$$
\textcircled{2} If the difference occurs in the branch power flow limits b, it is assumed that the model in the Step 2 is b+Δb, and the model corresponding to the system state to be compared with is the branch power flow limits b; if formula (5) is met, the two system states belong to the same COLM-set:
$${B}^{- 1} ( b + Δ b ) \geq 0 \qquad ( 5 )$$
the Lagrange multiplier λₛ of the system state s in the Step 1 is:
$${λ}_{s} = {c}_{B}^{T} {B}^{- 1} \qquad ( 6 )$$
\textcircled{3} If the difference occurs in a column vector pk in the coefficient matrix A, it is assumed that the model in the Step 2 is pₖ+Δpₖ, and the model corresponding to the system state to be compared with is the column vector pₖ; if the column vector pₖ does not belong to an optimal basis B, (i.e., the corresponding variable Xₖ is not the basic variable), and formula (7) is met, the two system states belong to the same COLM-set:
$${c}_{k} - {c}_{B}^{T} {B}^{- 1} ( {p}_{k} + Δ {p}_{k} ) \leq 0 \qquad ( 7 )$$
where Cₖ is the cost coefficient of the corresponding variable Xₖ; the Lagrange multiplier λₛ of the system state s in the Step 1 is:
$${λ}_{s} = {c}_{B}^{T} {B}^{- 1} \qquad ( 8 )$$
\textcircled{4} If the variable x changes, it is assumed that a new variable Xₙ₊₁ is added to the model of the system state to be compared in the Step 2; the cost coefficient Cₙ₊₁ and coefficient matrix column vector pₙ₊₁ are added accordingly; if formula (9) is met, the two system states belong to the same COLM-set:
$${c}_{n + 1} - {c}_{B}^{T} {B}^{- 1} {p}_{n + 1} \leq 0 \qquad ( 9 )$$
the Lagrange multiplier λₛ of the system state s in the Step 1) is:
$${λ}_{s} = {c}_{B}^{T} {B}^{- 1} \qquad ( 10 )$$
the maximum time of judgment criteria is proposed; if it is exceeded, an optimal load curtailment model with the same Lagrange multiplier λₛ is not found, and this optimal load curtailment model is regarded as a single set; and
comparing and judging the values of A, b, and c of the two models in descending order according to the similarity thereof, wherein
the method based on Lagrange multiplier in power system reliability assessment is implemented in such a way that the processor executing the method is integrated as a controller with the power system reliability assessment service, and then a power system uses the controller to use the data from the power system reliability assessment device to control the power system to reduce power consumption;
the method is applied to establish a power system reliability assessment device resulting in the power system reliability assessment device comprising an input and initialization module, a system state selection module, a state impact analysis module, and a reliability indices calculation module;
the input and initialization module is configured to input power system data, component reliability data, and preset parameters of reliability assessment methods, including topological structure, branch parameters, component parameters, load data, renewable generation locations, renewable generation output data, and reliability parameters of components;
the system state selection module is configured to select the system states to be analyzed for the reliability assessment, including component contingency state, load time sequence state, and renewable generation output time sequence state;
the state impact analysis module analyzes the impact of the system states selected by the system state selection module using the optimal load curtailment calculating method of Lagrange multiplier, and represents the impact by the load curtailments and all reliability indices;
the reliability indices calculation module is configured to compute the reliability indices of the power system based on impact analysis results of the system states; and
the power system reliability assessment device quantitatively assesses the power system risks with reliability indices is of guiding planning, design, operation, and maintenance of power systems.

2. A system for calculating an optimal load curtailment based on a Lagrange multiplier, comprising:
a power system; and
a power system reliability assessment device configured to communicate with the power system via a network;
the power system reliability assessment device comprises an input and initialization module, a system state selection module, a state impact analysis module, and a reliability indices calculation module; current transducers that measure the electrical current flowing through a circuit; voltage sensors that measure the electrical potential difference; power analyzers that provide comprehensive measurements of power; and energy monitors that measure and track energy consumption over time; and a power system controller that uses that information to automatically or remotely control the power flow to various electrical loads;
the input and initialization module is configured to input power system data, component reliability data, and preset parameters of reliability assessment methods, including topological structure, branch parameters, component parameters, load data, renewable generation locations, renewable generation output data, and reliability parameters of components;
the system state selection module is configured to select the system states to be analyzed for the reliability assessment, including component contingency state, load time sequence state, and renewable generation output time sequence state;
the state impact analysis module analyzes the impact of the system states selected by the system state selection module using a optimal load curtailment calculating method of Lagrange multiplier, and represents the impact by the load curtailments and all the reliability indices; and
the reliability indices calculation module is configured to compute the reliability indices of the power system based on impact analysis results of the system states;
the power system reliability assessment device comprises, the processor and a memory storing program instructions for applying an optimal load curtailment calculating method based on Lagrange multiplier in power system reliability assessment;
the optimal load curtailment calculating method based on Lagrange multiplier, comprising the following steps, when executed by the processor:
Step 1: inputting all system states s to be analyzed for reliability assessment, and establishing corresponding optimal load curtailment models, namely:
$$\begin{matrix}min & {c}^{T} x \\ s . t . & Ax = b , x \geq 0\end{matrix} \qquad ( 1 )$$
where x is a variable vector; A is a coefficient matrix; b is a right-hand-side vector;
c is a cost coefficient vector;
Step 2: classifying the above optimal load curtailment models into several sets by the Lagrange multiplier λₛ; and
Step 3: solving all the optimal load curtailment models in each set by the Lagrange multiplier λₛ of the set, to obtain optimal load curtailments f_{LC_s} of the system states;
wherein the Step 3 comprises a step as follows:
calculating the optimal load curtailments f_{LC_s} of the system states s by the Lagrange multiplier λₛ:
$${f}_{LC \_ s} = {λ}_{s} b \qquad ( 2 )$$
where b is determined by the optimal load curtailment model established in the Step 1;
wherein the Step 2 comprises the following steps:
comparing an unclassified optimal load curtailment model with a classified one, and the two models belong to the same set if the Lagrange multipliers of the two models are the same;
determining whether the Lagrange multipliers of the two optimal load curtailment models are the same comprises the following steps:
adopting the judgment criterion to determine whether the different vectors A, b, and c of the two models will lead to different Lagrange multipliers λₛ; wherein judgment criteria are as follows:
\textcircled{1} If the difference occurs in a cost coefficient vector c, wherein c is the cost coefficient vector c, it is assumed that the model in the Step 2 is c+Δc, and the model corresponding to the system state to be compared with is the vector c; if formula (3) is met, the two system states belong to the same COLM-set:
$${( c + Δ c )}^{T} - {( {c}_{B} + Δ {c}_{B} )}^{T} {B}^{- 1} A \leq 0 \qquad ( 3 )$$
as the cost coefficient vector c is different, the Lagrange multiplier λₛ of the system state s in the Step 1 is:
$${λ}_{s} = {( {c}_{B} + Δ {c}_{B} )}^{T} {B}^{- 1} \qquad ( 4 )$$
\textcircled{2} If the difference occurs in the branch power flow limits b, it is assumed that the model in the Step 2 is b+Δb, and the model corresponding to the system state to be compared with is the branch power flow limits b; if formula (5) is met, the two system states belong to the same COLM-set:
$${B}^{- 1} ( b + Δ b ) \geq 0 \qquad ( 5 )$$
the Lagrange multiplier λₛ of the system state s in the Step 1 is:
$${λ}_{s} = {c}_{B}^{T} {B}^{- 1} \qquad ( 6 )$$
\textcircled{3} If the difference occurs in a column vector pₖ in the coefficient matrix A, it is assumed that the model in the Step 2 is pₖ+Δpₖ, and the model corresponding to the system state to be compared with is the column vector pₖ; if the column vector pₖ does not belong to an optimal basis B, (i.e., the corresponding variable Xₖ is not the basic variable), and formula (7) is met, the two system states belong to the same COLM-set:
$${c}_{k} - {c}_{B}^{T} {B}^{- 1} ( {p}_{k} + Δ {p}_{k} ) \leq 0 \qquad ( 7 )$$
where Cₖ is the cost coefficient of the corresponding variable Xₖ; the Lagrange multiplier λₛ of the system state s in the Step 1 is:
$${λ}_{s} = {c}_{B}^{T} {B}^{- 1} \qquad ( 8 )$$
\textcircled{4} If the variable x changes, it is assumed that a new variable xₙ₊₁ is added to the model of the system state to be compared in the Step 2; the cost coefficient Cₙ₊₁ and coefficient matrix column vector pₙ₊₁ are added accordingly; if formula (9) is met, the two system states belong to the same COLM-set:
$${c}_{n + 1} - {c}_{B}^{T} {B}^{- 1} {p}_{n + 1} \leq 0 \qquad ( 9 )$$
the Lagrange multiplier λₛ of the system state s in the Step 1) is:
$${λ}_{s} = {c}_{B}^{T} {B}^{- 1} \qquad ( 10 )$$
the maximum time of judgment is proposed; if it is exceeded, an optimal load curtailment model with the same Lagrange multiplier λₛ is not found, and this optimal load curtailment model is regarded as a single set; and
comparing and judging the values of A, b, and c of the two models in descending order according to the similarity thereof;
wherein the method based on Lagrange multiplier in power system reliability assessment in is implemented in such a way that the processor executing the method is integrated as a part of the power system controller with the power system reliability assessment service, and then the power system used the power system controller to use the data from the power system reliability assessment device to control the power system; and wherein the power system reliability assessment device quantitatively assesses the power system risks with reliability indices is of guiding planning, design, operation, and maintenance of power systems.

3. The system of claim 2, wherein in the step “comparing an unclassified optimal load curtailment model with a classified one”, the Lagrange multiplier of the classified optimal load curtailment model is calculated by an optimization calculation method.
